(19) United States
(12) Patent Application Publication
(10) Pub. No.: US 2025/0357083 A1
(43) Pub. Date: Nov. 20, 2025

(54) Systems and Methods for Energizing Elements in Reactor Flow via Microwave

(71) Applicant: Rimere, LLC, Boulder, CO (US)

(72) Inventor: Garrett Hill, Boulder, CO (US)

(21) Appl. No.: 19/207,915

(22) Filed: May 14, 2025

Related U.S. Application Data
(60) Provisional application No. 63/647,262, filed on May 14, 2024.

(51) Int. Cl. H01J 37/32

(52) U.S. Cl. CPC H01J 37/32201; H01J 37/32229; H01J 37/32541

(57) ABSTRACT

Plasma generators and methods for reforming hydrocarbon feedstocks are disclosed. A hydrocarbon feedstock is fed into the reactor. An electrode and a microwave generator form and sustain a plasma in a first reaction zone. The plasma is propagated to a second, downstream, reaction zone where it reforms the feedstock into a hydrogen product and a carbonaceous byproduct. The carbonaceous byproduct is entrained or otherwise directed by flow elements of the reactor toward the electrode. A second microwave generator directs microwaves to the entrained carbonaceous byproduct, heating the byproduct and in turn the feedstock. Selectively heating the feedstock before reforming in the second reaction zone improves efficiency, performance, and yield of the reactor.

This application claims the benefit of priority to U.S. Provisional Patent No. 63/647,262 filed May 14, 2024, incorporated by reference in their entirety herein.

### FIELD OF THE INVENTION

The field of the invention is plasma systems.

### BACKGROUND

The background description includes information that may be useful in understanding the present invention. It is not an admission that any of the information provided herein is prior art or relevant to the presently claimed invention, or that any publication specifically or implicitly referenced is prior art.

All publications herein are incorporated by reference to the same extent as if each individual publication or patent application were specifically and individually indicated to be incorporated by reference. Where a definition or use of a term in an incorporated reference is inconsistent or contrary to the definition of that term provided herein, the definition of that term provided herein applies and the definition of that term in the reference does not apply.

It is increasingly desirable to process or reform fluids, gases, and contents thereof using plasmas, for example microwave plasmas. The yield, efficiency, or other performance indicators for such plasma systems can be greatly improved by preconditioning components or elements in the system. For example, plasma systems can be tuned to process or reform specific feedstocks into desired products. However, operating plasma systems at steady state conditions or for extended periods of time can be difficult and require reducing or minimizing active elements in the plasma system.

Thus, there remains a need for systems and methods to improve the performance of plasma systems without increasing complexity of the system or reducing productive operating capacity.

### SUMMARY OF THE INVENTION

Systems and methods using one or more plasmas to reform a feedstock are contemplated. A plasma generator for reforming a feedstock (preferably natural gas) into a product (preferably hydrogen) and a byproduct (preferably carbon) includes an electrode to generate a plasma in a reaction zone. The feedstock flows into the reaction zone from an upstream source, for example prior processing of the feedstock or a store or supply of the feedstock. Another (e.g., second) reaction zone is positioned downstream of the first reaction zone and receives the feedstock. The second reaction zone is configured to sustain another plasma therein, which is used to reform the feedstock into the product and the byproduct at least in part. The byproduct from the second reaction zone flows toward the electrode. For example, the first reaction zone, second reaction zone, or both can be configured to entrain a portion of the byproduct in a path of the first waveguide.

A waveguide is directed downstream of the electrode (e.g., between the electrode and the second reaction zone) and configured or tuned to emit a wave (preferably microwave) tuned to energize the byproduct, for example heating the byproduct. The byproduct flows toward the electrode and into a path of the waveguide, the waveguide is directed toward the byproduct or an accumulation or the byproduct, or some combination thereof.

The byproduct includes carbon, such as carbon particles, colloids, nanostructures, carbon black, soot, clumps, or other forms of solid carbon, as well as sulfur particulate or sulfur compounds, alone or in combinations thereof. In some embodiments the carbon is suspended in a gas or fluid flowing through the reaction zones or the system.

The wave is tuned to heat the byproduct, for example solid carbon in general or the combinations of carbon found in the byproduct. The heated byproduct in turn heats the feedstock as it flows through or past the byproduct. Heating of the feedstock has the unexpected advantage of improving system performance in reforming feedstock from hydrocarbon to carbon and hydrogen.

A second waveguide can be directed at the plasma in the first reaction zone, for example near a tip of the electrode or downstream of the electrode. The second waveguide energizes the plasma in the first reaction zone, and propagates or extends it from the first reaction zone toward the second reaction zone. The second reaction zone is configured to sustain the plasma therein, for example with one or more additional microwave generators or waveguides energizing the plasma in the second reaction zone. Surprisingly, heating the feedstock before treating it in the second reaction zone with the plasma improves reformation of hydrocarbons into carbon and hydrogen. The microwave directed toward the first reaction zone, or graphene heating zone, is preferably concentrated, focusing microwave energy onto a localized point for increased or maximum ignition field intensity.

A flow element can also be disposed between the electrode and the second reaction zone, wherein the flow element directs a flow of byproduct toward the electrode. The flow element can be a contour of the reaction zone, a fin, rod, obstruction, or protrusion in the reaction zone, or a contour or surface feature of an element in the reaction zone. The flow element can be the shape of the electrode or the electrode tip, configured to create negative or low pressure between the electrode and the second reaction zone. For example the electrode tip of a glide arc ignition system can create the low pressure zone downstream of the first reaction zone, which recirculates carbon or other byproduct from the second reaction zone back toward the first reaction zone, or a waveguide for heating the byproduct.

Viewed from another perspective, the flow element creates a negative or low pressure zone between the electrode and the second reaction zone, which draws byproduct carbon from the second reaction zone and entrains it in the low pressure zone. The flow element creates a flow dynamic that transports graphene from a downstream plasma toward an upstream microwave waveguide, the graphene heating zone. The waveguide is activated, directing microwaves at the graphene heating zone and heating the graphene flowing or suspended in the zone. Surprisingly, heating graphene in the graphene heating zone stabilizes or improves stability of downstream plasma reactions.

Further plasma generators are contemplated for reforming a feedstock into a product. An electrode is configured to generate a plasma in a reaction zone receiving a flow of the feedstock. Another reaction zone receives the flow of the feedstock downstream of the first reaction zone, and is configured to sustain a second plasma. The second plasma is sustained by additional electrodes or introducing energy into the reaction zone or the plasma, for example introducing microwave energy or high voltage energy by induction. The second plasma reforms the feedstock into the product, though it is contemplated the first plasma also reforms the feedstock into product.

A heating element is preferably positioned in the flow of the feedstock in the first reaction zone and energetically coupled to an energizing element. For example, the heating element is preferably energized by microwave energy (the energizing element is a microwave, waveguide, or microwave generator), but can also be energized by other EM wave energy, acoustic energy, conductive or thermal energy, chemical energy, or electrical energy (e.g., high voltage). The heating element is heated to at least 100° C., 150° C., 200° C., 300° C., or 500° C., up to 1,200° C. In some embodiments, the heating element stays cool (e.g., room temperature, system temperature, ambient temperature) in steady state conditions.

The heating element is made up of or includes a carbon byproduct from reforming the feedstock into the product, for example primarily graphene or other carbon structures (e.g., graphite), and in preferred cases the carbon byproduct is produced during concurrent use of the plasma system. For example, the carbon byproduct is produced in the second reaction zone and flows from the second reaction zone toward the electrode (e.g., toward the first reaction zone). The energizing element can be a waveguide configured to direct a wave at the heating element, or can be an induction coil tuned to heat the heating element (e.g., carbon byproduct). The heating element can also be an object placed between the electrode or the first reaction zone and the second reaction zone, either fixed or held in position, or suspended (e.g., levitating, floating), All or part(s) of the heating element preferably absorb microwave energy.

A second waveguide is optionally directed at the first plasma in the first reaction zone. The second waveguide energizes the first plasma and propagates it from the first reaction zone toward the second reaction zone or the second plasma. In some cases the first and second plasmas mix to form a mixture of two plasmas, though the first and second plasmas can also join to form a hybrid plasma, or combine continuously to form the first plasma, flowing to a hybrid plasma, and flowing to the second plasma.

A flow element is disposed between the electrode and the second reaction zone and directs a flow of byproduct toward the electrode. The flow element includes a shape of the electrode configured to create negative pressure between the electrode and the second reaction zone. The flow element can also include surface features of the first or second reaction zones (e.g., shape of zone, contours of zone boundaries, surface projections, objects suspended in the zone or passing through the zone, etc). The flow element can also be disposed along the boundaries of the zone, in the flow of the feedstock or plasma, and be coupled with or separate from the electrode.

Further methods of reforming a feedstock into a product are contemplated. A plasma is generated in a reaction zone receiving a flow of the feedstock. Another plasma is sustained, energized, or generated in a second reaction zone downstream of the first reaction zone. The second reaction zone receives the flow of the feedstock. The flow of the feedstock is heated at a point downstream of the first plasma using a heating element, and the heated feedstock is reformed by the second plasma into the product.

The heating element is at least one of a carbon byproduct from reforming the feedstock into the product, for example primarily graphene, graphite, or other carbonaceous byproduct from reforming the feedstock. The carbon byproduct flows from the second reaction zone toward the first plasma, for example on a draft or entraining flow. The heating element is energized, for example by a microwave, heating the heating element.

Various objects, features, aspects and advantages of the inventive subject matter will become more apparent from the following detailed description of preferred embodiments, along with the accompanying drawing figures in which like numerals represent like components.

### BRIEF DESCRIPTION OF THE DRAWING

FIG. 1 illustrates a plasma reactor of the inventive subject matter.

FIG. 2 illustrates another plasma reactor of the inventive subject matter.

FIG. 3 illustrates still another plasma reactor of the inventive subject matter.

FIG. 4A illustrates yet another plasma reactor of the inventive subject matter.

FIG. 4B illustrates a magnified view of box I from FIG. 4A.

FIG. 5A illustrates a view of an electrode of the inventive subject matter.

FIG. 5B illustrates another view of an electrode of the inventive subject matter.

FIG. 5C illustrates a view of part of an electrode of the inventive subject matter.

FIG. 5D illustrates a view of part of another electrode of the inventive subject matter.

FIG. 5E illustrates a view of part of yet another electrode of the inventive subject matter.

FIG. 5F illustrates a view of part of still another electrode of the inventive subject matter.

### DETAILED DESCRIPTION

The following description includes information that may be useful in understanding the present invention. It is not an admission that any of the information provided herein is prior art or relevant to the presently claimed invention, or that any publication specifically or implicitly referenced is prior art.

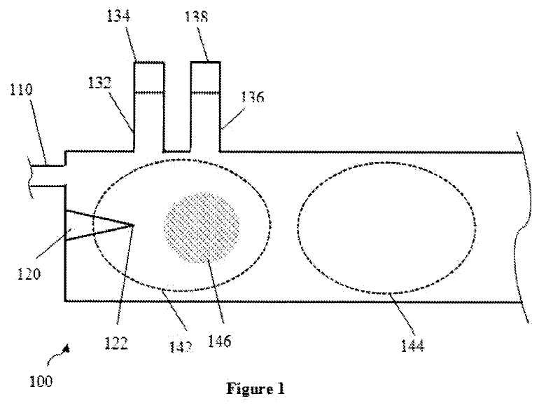

FIG. 1 depicts plasma reactor 100, having feedstock inlet 110, electrode 120, reaction zone 142, and reaction zone 144. Inlet 110 supplies feedstock to reactor 100, generally natural gas or other hydrocarbon feedstock. Electrode 120 is disposed within reactor 100 and configured to form a plasma in reactor 100, generally within reactor zone 142. In this embodiment, electrode 120 extends into reaction zone 142. Reactor 100 further includes microwave generator 134 paired with waveguide 132. Microwave generator 134 generates microwaves and waveguide 132 directs the microwaves toward reaction zone 142. Microwaves generated by microwave generator 134 energize the plasma formed by electrode 120 and cause it to propagate in reaction zone 142.

Reaction zone 144 is downstream of reaction zone 142 and is configured to sustain a plasma. For example, the plasma of reaction zone 142 can propagate to reaction zone 144, either extending the plasma, mixing with another plasma in reaction zone 144, or forming a hybrid plasma when combined with a plasma in reaction zone 144.

The plasmas of reactor 100 act upon hydrocarbon feedstock introduced into the reactor to form a hydrogen product and a carbonaceous byproduct. The carbonaceous byproduct is formed primarily in reaction zone 144, and is entrained or drawn toward reaction zone 142 by flow element 122. In this embodiment, the flow element is the tip or shape of electrode 120, but the flow element can also include further features or shapes in reactor 100 that cause carbonaceous byproduct to flow from reaction zone 144 toward reaction zone 142 or electrode 120.

Based on the design of features of reactor 100, carbonaceous byproduct will flow from reaction zone 144 toward reaction zone 142 or electrode 120 and condense or collect into a cloud or cluster of carbonaceous material, here depicted as carbon cloud 146 in reaction zone 142.

Reactor 100 further includes microwave 138 paired with microwave guide 136, which direct microwaves toward carbon cloud 146. Microwave energy from microwave generator 138 acts upon carbon cloud 146 to heat the cloud, for example heating the cloud to between 50° C. and 550° C. Heating cloud 146 in turn heats feedstock of reactor 100 as the feedstock flows through the reactor, for example flowing from reaction zone 142 toward reaction zone 144. Heating feedstock as it flows through reactor 100 increases the reformation of hydrocarbon feedstock to hydrogen and carbon and improves the performance of reactor 100.

Carbonaceous byproduct can be collected or caused to coalesce or condense throughout the flow of reactor 100. Thus multiple additional microwave generators or waveguides can be used to energize carbonaceous byproduct throughout reactor 100, heating feedstock in the system an improving the yield or efficiency of producing hydrogen.

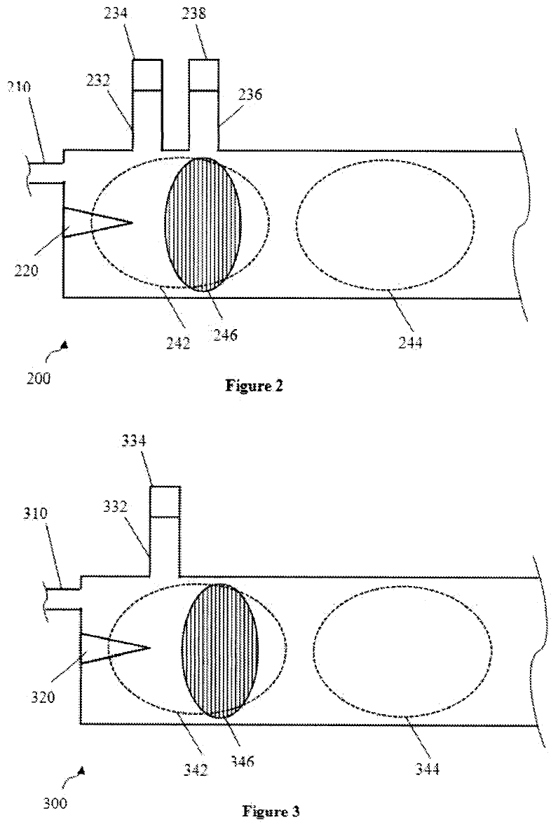

FIG. 2 depicts plasma reactor 200, having inlet 210, electrode 220, reaction zone 242, reaction zone 244, paired microwave generator 234 and waveguide 232, and paired microwave generator 238 and waveguide 236. These features are similar to and as described by the elements of FIG. 1. Reactor 200 further includes heating element 246 disposed between electrode 220 and reaction zone 244. Heating element 246 can be a grate, grid, or mesh, or other solid or semi-solid structure suspended in or spanning the flow of feedstock in reactor 200 such that flow of feedstock through the reactor may be maintained. Heating element 246 is energized by paired microwave generator 238 and waveguide 236, which heats heating element 246 and in turn heats feedstock in reactor 200. As noted above, heating feedstock in reactor 200 increases production of hydrogen in the reactor.

FIG. 3 depicts plasma reactor 300, having feedstock inlet 310, electrode 320, reaction zone 342, reaction zone 344, heating element 246, and paired microwave generator 334 and waveguide 332. These features are similar to and as described by the elements of FIGS. 1 and 2. Reactor 300 includes heating element 346 disposed between electrode 320 and reaction zone 344. Heating element 346 can be a grate, grid, or mesh, or other solid or semi-solid structure suspended in or spanning the flow of feedstock in reactor 300 such that flow of feedstock through the reactor may be maintained. Heating element 346 is energized directly by electric cabling coupled to heating element 346 (not depicted) or by induction (not depicted). The heating of heating element 346 in turn heats feedstock in reactor 200. As noted above, heating feedstock in reactor 200 increases production of hydrogen in the reactor.

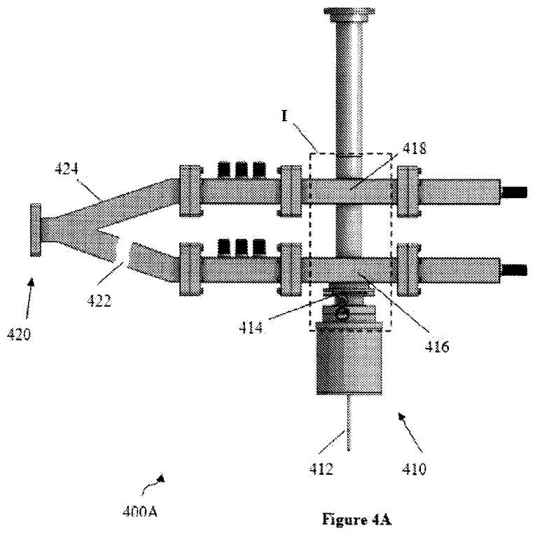

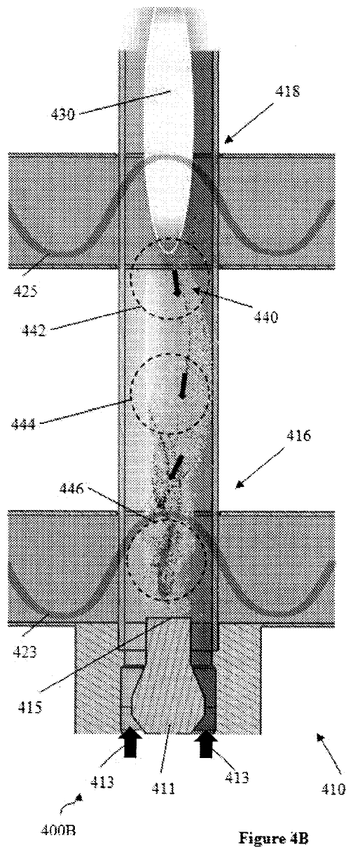

FIG. 4A depicts plasma reactor 400A, which includes reactor channel 410 and microwave source 420. Reactor channel 410 includes input 412 which introduces a feedstock to the reactor, for example methane, natural gas, or other hydrocarbons. Downstream of input 412 is ignition zone 414, where a plasma is ignited to reform the feedstock in reactor 400A. Reaction zone 416 is downstream of ignition zone 414, and intersects with waveguide 422 and microwaves therefrom. Reaction zone 418 is downstream of ignition zone 416 and intersects with waveguide 424 and microwaves therefrom.

Microwave source 420 can simultaneously provide microwaves for microwave guides 422 and 424. Preferably, waveguide 422 is isolated or independent from waveguide 424, providing precise control over power or energy deposition of microwaves into byproducts in reaction zone 416, for example graphene, while maintaining plasmas or other reactive activities at reaction zone 418 or other downstream reaction zones.

Box I indicates a portion of reactor 400A that is magnified and further detailed in FIG. 4B.

FIG. 4B depicts portion 400B of reactor 400A enclosed in FIG. 4A by box I. Reactor channel 410 includes electrode 411 with electrode tip 415, inputs 413 denoted by arrows for supplying feedstock to the reactor, preferably methane, and reaction zones 416 and 418. Reaction zone 416 intersects with microwave 423 from waveguide 422. Reaction zone 418 intersects with microwave 425 from waveguide 424. Plasma 430 is energized in reaction zone 418 (e.g., from microwave 425 or other sources) and extends downstream from reaction zone 418. Plasma 430 reforms feedstock (e.g., methane, natural gas, other hydrocarbons, etc.) in reactor 400A, producing in part hydrogen gas (H2) and carbonaccous byproduct, preferably graphene 440. Electrode tip 415 is shaped to create flow dynamics (e.g., negative pressure, cyclone, etc.) in reactor channel 410 between reaction zones 416 and 418 to draw graphene 440 from reaction zone 418 toward reaction zone 416 (see arrows indicated flow direction and graphene 440 in dashed circles 442, 444, and 446.) Graphene 440 is drawn into reaction zone 416, where it is energized by microwave 423 and heated (see dashed circle 446). Heated graphene in reaction zone 416 (or circle 446) improves efficiency of reactor 400A, increases production of hydrogen gas from reactor 400A, increases production of graphene from reactor 400A, or stabilizes plasma reactions of reactor 400A downstream from reaction zone 416.

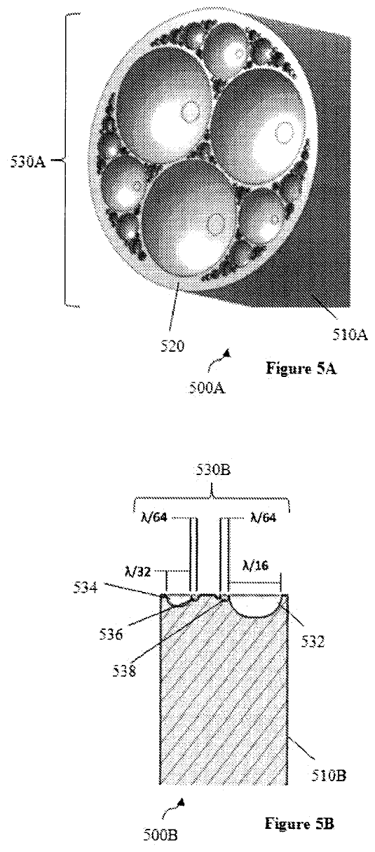

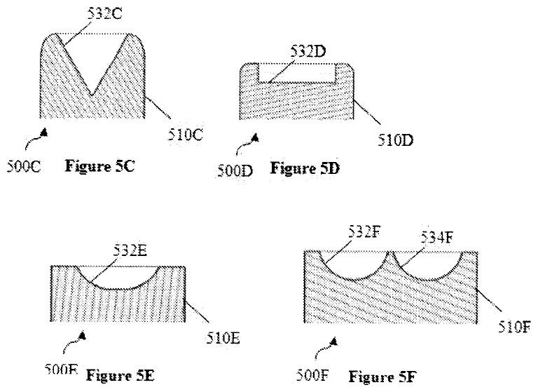

FIG. 5A depicts electrode 500A, including electrode body 510A and electrode tip 520. Electrode tip 520 includes a number of surface features 530A arranged on the surface of electrode tip 520. Surface features 530A create flow dynamics in plasma reactors of the inventive subject matter that draw carbonaceous byproducts or graphene from downstream of electrode 500A toward electrode 500A.

FIG. 5B depicts electrode 500B, including electrode body 510B and surface features 530B at a tip of electrode 500B. In some embodiments surface features 530B are designed to have dimensions corresponding to the wavelengths of microwaves directed toward electrode 500B. Surface features 530B include feature 532, a curved pit having a diameter or width of 1/16 the wavelength of a microwave directed toward electrode 500B. Feature 534 is curved pit having a diameter or width of 1/32 the wavelength of a microwave directed toward electrode 500B, while features 536 and 538 are similar shapes with widths 1/64 such a wavelength.

FIG. 5C depicts electrode 500C having electrode body 510C and feature 532C, an angular pitted shape. It is contemplated dimensions of feature 532C (e.g., width, depth, angle of decline, etc.) have a proportional relationship with a microwave directed toward electrode 500C, for example a fraction of the wavelength.

FIG. 5D depicts electrode 500D having electrode body 510D and feature 532D, an squared pitted shape. It is contemplated dimensions of feature 532D (e.g., width, depth, angle of decline, etc.) have a proportional relationship with a microwave directed toward electrode 500D, for example a fraction of the wavelength.

FIG. 5E depicts electrode 500E having electrode body 510E and feature 532E, a curved pit. It is contemplated dimensions of feature 532E (e.g., width, depth, curvature, etc.) have a proportional relationship with a microwave directed toward electrode 500E, for example a fraction of the wavelength.

FIG. 5F depicts electrode 500F having electrode body 510F and features 532F and 534F, a pair of curved pits. It is contemplated dimensions of features 532F and 534F (e.g., width, depth, curvature, etc.) have a proportional relationship with a microwave directed toward electrode 500F, for example a fraction of the wavelength.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously.

Unless the context dictates the contrary, all ranges set forth herein should be interpreted as being inclusive of their endpoints, and open-ended ranges should be interpreted to include commercially practical values. Similarly, all lists of values should be considered as inclusive of intermediate values unless the context indicates the contrary.

The recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g. “such as”) provided with respect to certain embodiments herein is intended merely to better illuminate the invention and does not pose a limitation on the scope of the invention otherwise claimed. No language in the specification should be construed as indicating any non-claimed element essential to the practice of the invention.

Groupings of alternative elements or embodiments of the invention disclosed herein are not to be construed as limitations. Each group member can be referred to and claimed individually or in any combination with other members of the group or other elements found herein. One or more members of a group can be included in, or deleted from, a group for reasons of convenience and/or patentability. When any such inclusion or deletion occurs, the specification is herein deemed to contain the group as modified thus fulfilling the written description of all Markush groups used in the appended claims.

The following discussion provides many example embodiments of the inventive subject matter. Although each embodiment represents a single combination of inventive elements, the inventive subject matter is considered to include all possible combinations of the disclosed elements. Thus if one embodiment comprises elements A, B, and C, and a second embodiment comprises elements B and D, then the inventive subject matter is also considered to include other remaining combinations of A, B, C, or D, even if not explicitly disclosed.

It should be apparent to those skilled in the art that many more modifications besides those already described are possible without departing from the inventive concepts herein. The inventive subject matter, therefore, is not to be restricted except in the scope of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refers to at least one of something selected from the group consisting of A, B, C . . . and N, the text should be interpreted as requiring only one element from the group, not A plus N, or B plus N, etc.

What is claimed is:

1. A plasma generator for reforming a feedstock into a product and a byproduct comprising:
an electrode configured to generate a first plasma in a first reaction zone receiving a flow of the feedstock;
a second reaction zone receiving the flow of the feedstock downstream of the first reaction zone and configured to sustain a second plasma, wherein the second plasma reforms the feedstock into the product and the byproduct; and
a first waveguide directed downstream of the electrode and configured to emit a wave tuned to energize the byproduct;
wherein at least one of the first reaction zone or second reaction zone is configured to entrain at least a portion of the byproduct in a path of the first waveguide.

2. The generator of claim 1, wherein the byproduct comprises particulate carbon.

3. The generator of claim 1, further comprising a second waveguide directed at the first plasma in the first reaction zone.

4. The generator of claim 3, wherein the second waveguide energizes the first plasma and propagates it from the first reaction zone to the second reaction zone.

5. The generator of claim 1, wherein the wave is tuned to heat the byproduct.

6. The generator of claim 5, wherein the heated byproduct heats the flow of the feedstock.

7. The generator of claim 1, further comprising a flow element disposed between the electrode and the second reaction zone, wherein the flow element directs a flow of byproduct toward the electrode.

8. The generator of claim 7, wherein the flow element comprises a shape of the electrode configured to create negative pressure between the electrode and the second reaction zone.

9. A plasma generator for reforming a feedstock into a product comprising:
an electrode configured to generate a first plasma in a first reaction zone receiving a flow of the feedstock;
a second reaction zone receiving the flow of the feedstock downstream of the first reaction zone and configured to sustain a second plasma, wherein the second plasma reforms the feedstock into the product;
a heating element positioned in the flow of the feedstock in the first reaction zone; and
an energizing element energetically coupled to the heating element;
wherein the heating element is heated to at least 100° C.

10. The generator of claim 9, wherein the heating element comprises at least one of a carbon byproduct from reforming the feedstock into the product or graphite.

11. The generator of claim 10, wherein the carbon byproduct flows from the second reaction zone toward the electrode.

12. The generator of claim 10, wherein the energizing element comprises a waveguide configured to direct a wave at the heating element.

13. The generator of claim 19, further comprising a second waveguide directed at the first plasma in the first reaction zone.

14. The generator of claim 13, wherein the second waveguide energizes the first plasma and propagates it from the first reaction zone to the second reaction zone.

15. The generator of claim 9, wherein the energizing element comprises an induction coil tuned to heat the heating element.

16. The generator of claim 9, further comprising a flow element disposed between the electrode and the second reaction zone, wherein the flow element directs a flow of byproduct toward the electrode.

17. The generator of claim 16, wherein the flow element comprises a shape of the electrode configured to create negative pressure between the electrode and the second reaction zone.

18. A method of reforming a feedstock into a product comprising:
generating a first plasma in a first reaction zone receiving a flow of the feedstock;
sustaining a second plasma in a second reaction zone receiving the flow of the feedstock downstream of the first reaction zone;
heating the flow of the feedstock at a point downstream of the first plasma using a heating element; and
reforming the heated feedstock into the product with the second plasma.

19. The method of claim 18, wherein the heating element comprises at least one of a carbon byproduct from reforming the feedstock into the product or graphite.

20. The method of claim 19, wherein the carbon byproduct flows from the second reaction zone toward the first plasma.

21. The method of claim 18, further comprising energizing the heating element with a microwave.
